(19) United States
(12) Patent Application Publication
(10) Pub. No.: US 2022/0414499 A1
(43) Pub. Date: Dec. 29, 2022

(54) PROPERTY PREDICTION SYSTEM FOR SEMICONDUCTOR ELEMENT

(71) Applicant: Semiconductor Energy Laboratory Co., Ltd., Atsugi-shi, Kanagawa-ken (JP)

(72) Inventors: Shunsuke HOSOUMI, Fujisawa (JP); Kunihiko SUZUKI, Isehara (JP); Kanta ABE, Atsugi (JP); Yuji IWAKI, Isehara (JP); Daigo SHIMADA, Atsugi (JP); Etsuko KAMATA, Isehara (JP)

(21) Appl. No.: 17/773,868

(22) PCT Filed: Nov. 6, 2020
(86) PCT No.: PCT/IB2020/060440

§ 371 Date: May 3, 2022

(30) Foreign Application Priority Data
Nov. 15, 2019 (JP) 2019-207258

(51) Int. Cl. G06N 5/04; H01L 21/66

(52) U.S. Cl. CPC G06N 5/04; H01L 22/10

(57) ABSTRACT

A property prediction system for a semiconductor element is provided. The property prediction system includes a memory unit, an input unit, a processing unit, and an arithmetic unit. The processing unit has a function of creating a learning data set from first data stored in the memory unit, a function of creating prediction data from second data supplied from the input unit, a function of converting qualitative data (a material name or a compositional formula) into quantitative data (the properties of an element and a composition), and a function of performing extraction or removal on the first data and the second data. The first data includes step lists of first to m-th semiconductor elements (m is an integer of 2 or more) and the properties of the first to m-th semiconductor elements. The second data includes a step list of an (m+1)-th semiconductor element. The arithmetic unit having a function of performing learning and inference of supervised learning performs learning on the basis of the learning data set and makes an inference of a semiconductor element from the prediction data.

### TECHNICAL FIELD

One embodiment of the present invention relates to a property prediction system for a semiconductor element. Another embodiment of the present invention relates to a method for predicting the properties of a semiconductor element.

Note that a semiconductor element in this specification and the like refers to an element that can function by utilizing semiconductor characteristics. Examples of the semiconductor element are semiconductor elements such as a transistor, a diode, a light-emitting element, and a light-receiving element. Other examples of the semiconductor element are passive elements such as a capacitor, a resistor, and an inductor, which are formed using a conductive film, an insulating film, or the like. Still another example of the semiconductor element is a semiconductor device provided with a circuit including a semiconductor element or a passive element.

### BACKGROUND ART

In recent years, a novel semiconductor element has been developed to resolve an issue such as an increase in computational complexity or an increase in power consumption, in a field using artificial intelligence (AI), a robotic field, or a field needing high power energy for power ICs or the like. Integrated circuits demanded by markets or semiconductor elements used in the integrated circuits have become more complicated; meanwhile, an early startup of integrated circuits having novel functions has been demanded. For the process design, device design or circuit design in the development of semiconductor elements, knowledge, know-how, experience, or the like of skilled engineers is required.

In recent years, a method for optimizing the manufacturing process, a method for estimating device properties, and the like have been proposed regarding semiconductor devices. Patent Document 1 discloses a method for calculating an image feature value from a SEM image of a cross-sectional pattern of a semiconductor device and estimating device properties of an evaluation target pattern from the correspondence between the image feature value and device properties.

### REFERENCE

### Patent Document

[Patent Document 1] Japanese Published Patent Application No. 2007-129059

### SUMMARY OF THE INVENTION

### Problems to be Solved by the Invention

A manufacturing process of a semiconductor element involves many steps to complete the semiconductor element and there are also wide-ranging kinds of steps and processing conditions. For the semiconductor element manufactured through many steps, the properties of the semiconductor element, such as the electrical characteristics and reliability test results, are measured with a measurement apparatus. The causal relationships between the manufacturing process of the semiconductor element and the properties of the semiconductor element are examined one by one through examination to improve the properties of the semiconductor element.

However, it takes a lot of cost and time to adjust the manufacturing process of the semiconductor element comprehensively and examine the causal relationships between the manufacturing process and the properties of the semiconductor element. Furthermore, it is also difficult for a human to grasp a huge amount of data. Therefore, optimizing the manufacturing process by examination requires a great deal of labor.

In view of the above, an object of one embodiment of the present invention is to provide a property prediction system for a semiconductor element. Another object of one embodiment of the present invention is to provide a method for predicting the properties of a semiconductor element. Another object of one embodiment of the present invention is to provide a learning data set for property prediction of a semiconductor element.

Note that the descriptions of these objects do not preclude the existence of other objects. One embodiment of the present invention does not have to achieve all these objects. Note that other objects will be apparent from the descriptions of the specification, the drawings, the claims, and the like, and other objects can be derived from the descriptions of the specification, the drawings, the claims, and the like.

### Means for Solving the Problems

One embodiment of the present invention is a property prediction system for a semiconductor element, the property prediction system performing learning of supervised learning on the basis of a learning data set and making an inference of the properties of a semiconductor element from prediction data on the basis of a result of the learning. The property prediction system for a semiconductor element includes a memory unit, an input unit, a processing unit, and an arithmetic unit. The processing unit has a function of creating the learning data set from first data stored in the memory unit, a function of creating the prediction data from second data supplied from the input unit, a function of converting qualitative data into quantitative data, and a function of performing extraction or removal on the first data and the second data. The first data includes step lists of a first semiconductor element to an m-th semiconductor element (m is an integer of 2 or more) and the properties of the first semiconductor element to the m-th semiconductor element. The second data includes a step list of an (m+1)-th semiconductor element. The qualitative data is a material name or a compositional formula. The quantitative data is the properties of an element and a composition. The arithmetic unit has a function of performing learning and inference of the supervised learning.

In the property prediction system for a semiconductor element, the properties of the element are preferably any one or more of an atomic number, a group, a period, an electron configuration, an atomic weight, an atomic radius (a covalent bond radius, a Van der Waals force radius, an ionic radius, or a metal bond radius), an atomic volume, an electronegativity, an ionized energy, an electron affinity, a dipole polarizability, an elemental melting point, an elemental boiling point, an elemental lattice constant, an elemental density, and an elemental heat conductivity.

In the property prediction system for a semiconductor element, the properties of the semiconductor element are preferably change in ΔVsh over time obtained by a reliability test (a +GBT stress test, a +DBT stress test, a −GBT stress test, a +DGBT stress test, a +BGBT stress test, or a −BGBT stress test). In the property prediction system for a semiconductor element, the properties of the semiconductor element are preferably the Id-Vg characteristics or the Id-Vd characteristics.

In the property prediction system for a semiconductor element, the processing unit preferably has a function of quantifying the qualitative data using Label Encoding.

### Effect of the Invention

One embodiment of the present invention can provide a property prediction system for a semiconductor element. Another embodiment of the present invention can provide a method for predicting the properties of a semiconductor element. Another embodiment of the present invention can provide a learning data set for property prediction of a semiconductor element.

Note that the effects of embodiments of the present invention are not limited to the effects listed above. The effects listed above do not preclude the existence of other effects. Note that the other effects are effects that are not described in this section and will be described below. The effects that are not described in this section can be derived from the descriptions of the specification, the drawings, and the like and can be extracted from these descriptions by those skilled in the art. Note that one embodiment of the present invention has at least one of the effects listed above and/or the other effects. Accordingly, depending on the case, one embodiment of the present invention does not have the effects listed above in some cases.

### BRIEF DESCRIPTION OF THE DRAWINGS

FIG. 1A and FIG. 1B are diagrams illustrating examples of a property prediction system for a semiconductor element.

FIG. 2 is a flow chart showing an example of a method for predicting the properties of a semiconductor element.

FIG. 3A and FIG. 3B are diagrams illustrating a neural network structure.

FIG. 4A and FIG. 4B are diagrams illustrating learning data sets.

FIG. 5A is a diagram showing results obtained by a reliability test of a semiconductor element. FIG. 5B is a diagram showing the Id-Vg characteristics of a semiconductor element.

FIG. 6A to FIG. 6C are diagrams showing a method for creating input data.

FIG. 7A and FIG. 7B are diagrams showing a method for creating input data.

FIG. 8 is a diagram illustrating a computer device.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below.

Note that in structures of the present invention described below, the same reference numerals are used in common for the same portions or portions having similar functions in different drawings, and a repeated description thereof is omitted. Furthermore, the same hatch pattern is used for the portions having similar functions, and the portions are not especially denoted by reference numerals in some cases.

In addition, the position, size, range, or the like of each structure illustrated in drawings does not represent the actual position, size, range, or the like in some cases for easy understanding. Therefore, the disclosed invention is not necessarily limited to the position, size, range, or the like disclosed in the drawings.

Furthermore, ordinal numbers such as “first”, “second”, and “third” used in this specification and the like are used in order to avoid confusion among components, and the terms do not limit the components numerically.

### Embodiment 1

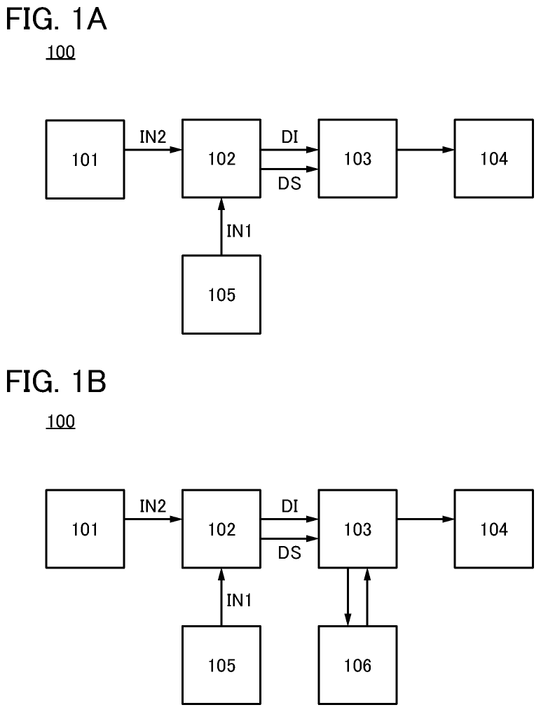

In this embodiment, a property prediction system for a semiconductor element and a method for predicting the properties of a semiconductor element, which are embodiments of the present invention, will be described with reference to FIG. 1A to FIG. 8.

The property prediction system for a semiconductor element which is one embodiment of the present invention is a system that can predict the properties of a semiconductor element from information on the semiconductor element. The method for predicting the properties of a semiconductor element which is one embodiment of the present invention is a method for predicting the properties of a semiconductor element using machine learning.

### Property Prediction System for Semiconductor Element

FIG. 1A is a diagram illustrating a structure of a property prediction system 100. That is, FIG. 1A can also be regarded as a structure example of the property prediction system for a semiconductor element which is one embodiment of the present invention.

The property prediction system 100 may be provided in an information processing device such as a personal computer used by a user. Alternatively, a processing unit of the property prediction system 100 may be provided in a server to be accessed by a client PC via a network and used.

As illustrated in FIG. 1A, the property prediction system 100 includes an input unit 101, a processing unit 102, an arithmetic unit 103, an output unit 104, and a memory unit 105. The input unit 101, the processing unit 102, the arithmetic unit 103, the output unit 104, and the memory unit 105 may be connected to each other through a transmission path.

The memory unit 105 stores data of information on a plurality of semiconductor elements. Examples of information on a semiconductor element include a step list of the semiconductor element, the properties of the semiconductor element, and information on the shape of the semiconductor element. Hereinafter, data on a step list of a semiconductor element is simply referred to as a step list of a semiconductor element in some cases. In addition, data on the properties of a semiconductor element is simply referred to as the properties of a semiconductor element in some cases. Furthermore, data of information on the shape of a semiconductor element is simply referred to as information on the shape of a semiconductor element in some cases.

In a step list of a semiconductor element, a plurality of steps are set in the order of manufacturing steps of the semiconductor element and processing conditions are specified for each of the steps.

Examples of the properties of a semiconductor element include the electrical characteristics of the semiconductor element and results of a reliability test, which are obtained by measurement with a measurement apparatus. Examples of data on the properties of a semiconductor element include measurement data on the electrical characteristics of the semiconductor element and data obtained by performing a reliability test.

Examples of information on the shape of a semiconductor element include the position, size, and range of components of the semiconductor element. Examples of data of information on the shape of a semiconductor element include numerical data representing the position, size, range, and the like of components of the semiconductor element, and image data of the semiconductor element and its periphery. Specific examples are measurement data on the channel length and the channel width, an observed image of a scanning electron microscope (SEM), and an observed image of a transmission electron microscope (TEM).

The memory unit 105 stores at least the step lists and the properties of the plurality of semiconductor elements. Note that an ID is preferably assigned to each of the step lists of the semiconductor elements stored in the memory unit 105. Here, the ID assigned to the step list of the semiconductor element is referred to as a step list ID. The properties of the semiconductor element stored in the memory unit 105 is associated with the step list ID. Therefore, reading, writing, and the like of the properties of the semiconductor element are performed on the basis of the step list ID in some cases.

The memory unit 105 may store information on the shapes of the plurality of semiconductor elements. In this case, the information on the shape of the semiconductor element stored in the memory unit 105 is preferably associated with the step list ID. In this case, reading, writing, and the like of the information on the shape of the semiconductor element are performed on the basis of the step list ID in some cases.

The step lists of the plurality of semiconductor elements and the properties of the plurality of the semiconductor elements are stored in the memory unit 105 through the input unit 101, a memory medium, communication, or the like. In addition, the information on the shapes of the plurality of semiconductor elements is preferably stored in the memory unit 105 through the input unit 101, a memory medium, communication, or the like.

The step lists of the plurality of semiconductor elements and the properties of the plurality of semiconductor elements are preferably stored in the memory unit 105 as text data. In particular, the properties of the plurality of semiconductor elements are preferably stored in the memory unit 105 as numerical data or bivariate data. In this specification and the like, the bivariate data refers to a data set relating to two variables. Note that the bivariate data may be a data set obtained by extracting data on two variables from multivariate data of three or more variables.

In the case where the step lists of the plurality of semiconductor elements and the properties of the plurality of semiconductor elements are image data, the image data may be stored in the memory unit 105 as it is, but the image data is preferably stored in the memory unit 105 after being converted into text data. Since the data size of text data is smaller than the data size of image data, storing image data in the memory unit 105 after conversion into text data can reduce the load on the memory unit 105.

The property prediction system 100 may have an optical character recognition (OCR) function. This enables characters contained in image data to be recognized and text data to be created. For example, the processing unit 102 may have the function. Alternatively, the property prediction system 100 may further include a character recognition unit having the function.

The memory unit 105 may have a function of storing a learned model (also referred to as an inference model).

The input unit 101 has a function of enabling a user to input data IN2. The data IN2 is text data or image data. Examples of the input unit 101 include an input device such as a keyboard, a mouse, a touch sensor, a scanner, or a camera. Note that the data IN2 may be stored in the memory unit 105.

In the case where the data IN2 is image data, the property prediction system 100 having the OCR function can recognize characters contained in the image data and create text data. For example, in the case where the processing unit 102 has the OCR function, the data IN2 may remain image data. Alternatively, in the case where a component of the property prediction system 100 other than the processing unit 102 has the OCR function, text data converted from image data may be used as the data IN2.

The processing unit 102 has a function of generating a learning data set DS from data IN1 that is supplied from the memory unit 105. The learning data set DS is a learning data set for supervised learning. Furthermore, the processing unit 102 has a function of generating prediction data DI from the data IN2 that is supplied from the input unit 101. The prediction data DI is data for property prediction of a semiconductor element.

The data IN1 is a data group used at the time of creating the learning data set DS. The data group includes information on some or all of the plurality of semiconductor elements stored in the memory unit 105.

Here, some or all of the plurality of semiconductor elements are referred to as a semiconductor element 30_1 to a semiconductor element 30_m (m is an integer of 2 or more). At this time, step lists of the semiconductor element 30_1 to the semiconductor element 30_m are a step list 10_1 to a step list 10_m, respectively. In addition, the properties of the semiconductor element 30_1 to the semiconductor element 30_m measured using a measurement apparatus are properties 20_1 to properties 20_m, respectively. That is, the properties 20_1 to the properties 20_m are properties obtained by performing measurement using a measurement apparatus on the semiconductor elements fabricated in accordance with the step list 10_1 to the step list 10_m, respectively.

Hereinafter, the step list 10_1 to the step list 10_m are collectively referred to as a plurality of step lists 10 in some cases. The properties 20_1 to the properties 20_m are collectively referred to as a plurality of properties 20 in some cases. The semiconductor element 30_1 to the semiconductor element 30_m are collectively referred to as a plurality of semiconductor elements 30 in some cases.

The data IN1 includes, for example, data on the step list 10_1 to the step list 10_m and data on the properties 20_1 to the properties 20_m. The data IN1 may include data of information on the shapes of the semiconductor elements, which are associated with the step lists ID of the step list 10_1 to the step list 10_m. Hereinafter, data on the step list 10_1 to the step list 10_m are simply referred to as the step list 10_1 to the step list 10_m in some cases. In addition, data on the properties 20_1 to the properties 20_m are simply referred to as the properties 20_1 to the properties 20_m in some cases.

The data IN2 is information on a semiconductor element specified by a user for property prediction of the semiconductor element. The data IN2 includes, for example, a step list specified for property prediction of the semiconductor element. The step list specified for property prediction of the semiconductor element is referred to as a step list 11. The data IN2 may include information on the shape of the semiconductor element associated with the step list ID of the step list 11.

The processing unit 102 has a function of quantifying qualitative data (also referred to as category data, categorical data, or the like). In other words, the processing unit 102 has a function of converting qualitative data into quantitative data (also referred to as numerical data or the like). For example, Label Encoding, One-hot Encoding, Target Encoding, or the like is preferably implemented in the processing unit 102.

Qualitative data is included in the data IN1 and the data IN2. Examples of qualitative data include data on an apparatus and data on a material. Quantification of qualitative data on an apparatus and qualitative data on a material will be described later.

The arithmetic unit 103 has a function of performing machine learning. For example, the arithmetic unit 103 preferably has a function of performing learning of supervised learning on the basis of the learning data set DS. The arithmetic unit 103 preferably has a function of making an inference of the properties of a semiconductor element from the prediction data DI on the basis of the learning result of the supervised learning. When learning of the supervised learning is performed as the machine learning, the accuracy of the inference of the properties of the semiconductor element can be improved. Note that a learned model may be generated by learning of the supervised learning.

For the supervised learning, a neural network (especially, deep learning) is preferably used. For the deep learning, a convolutional neural network (CNN), a recurrent neural network (RNN), an autoencoder (AE), a variational autoencoder (VAE), random forest, a support vector machine, gradient boosting, a generative adversarial network (GAN), or the like is preferably used, for example.

An output of the arithmetic unit 103 is the properties of a semiconductor element. That is, an output of a neural network is the properties of a semiconductor element. When a measurement value is used as the output of the neural network, learning of a machine learning model is performed and then a step list of a given semiconductor element is input to the neural network, so that the properties of the semiconductor element can be predicted.

Note that a product-sum operation is performed in a neural network. When the product-sum operation is performed using hardware, the arithmetic unit 103 preferably includes a product-sum operation circuit. A digital circuit may be used or an analog circuit may be used as the product-sum operation circuit. Note that the product-sum operation may be performed on software using a program.

The arithmetic unit 103 may have a function of performing semi-supervised learning as machine learning. The properties of a semiconductor element are supplied as training data (also referred to as a training signal, a correct label, or the like) for learning data; in order to prepare the training data, a semiconductor element needs to be actually fabricated to measure the properties of the semiconductor element. In semi-supervised learning, the number of learning data included in a learning data set can be smaller than that in supervised learning; thus, inference can be performed while the time spent for creating learning data is shortened.

The output unit 104 has a function of supplying information. The information is prediction results of the properties of a semiconductor element calculated in the arithmetic unit 103 or information on the prediction results. The information is supplied as, for example, visual information such as a character string, a numerical value, or a graph. An example of the output unit 104 is an output device such as a display. Note that the property prediction system 100 does not necessarily include the output unit 104.

As described above, the property prediction system for a semiconductor element is formed.

Note that the structure of the property prediction system 100 is not limited to the above. For example, as illustrated in FIG. 1B, the property prediction system 100 may include a storage unit 106 in addition to the input unit 101, the processing unit 102, the arithmetic unit 103, the output unit 104, and the memory unit 105.

The storage unit 106 has a function of storing a learned model generated by the arithmetic unit 103. When the property prediction system 100 includes the storage unit 106, the properties of a semiconductor element can be predicted on the basis of the learned model. Thus, when a learned model is generated in advance, learning of supervised learning is not necessarily performed in property prediction of a semiconductor element. Therefore, the time needed for property prediction of a semiconductor element can be shortened.

The storage unit 106 is connected to the arithmetic unit 103 through a transmission path. Note that the storage unit 106 may be connected to each of the input unit 101, the processing unit 102, the output unit 104, and the memory unit 105 through a connection path.

Note that the storage unit 106 may be provided in the memory unit 105. Alternatively, the memory unit 105 may also serve as the storage unit 106.

The above is the description of the structure of the property prediction system 100. With the use of the property prediction system for a semiconductor element which is one embodiment of the present invention, the properties of a semiconductor element can be predicted from information on the semiconductor element. For example, the properties of the semiconductor element can be predicted from the step list of the semiconductor element. In addition, a step that makes a large contribution to the properties of the semiconductor element can be extracted from the step list of the semiconductor element.

### Method for Predicting Properties of Semiconductor Element

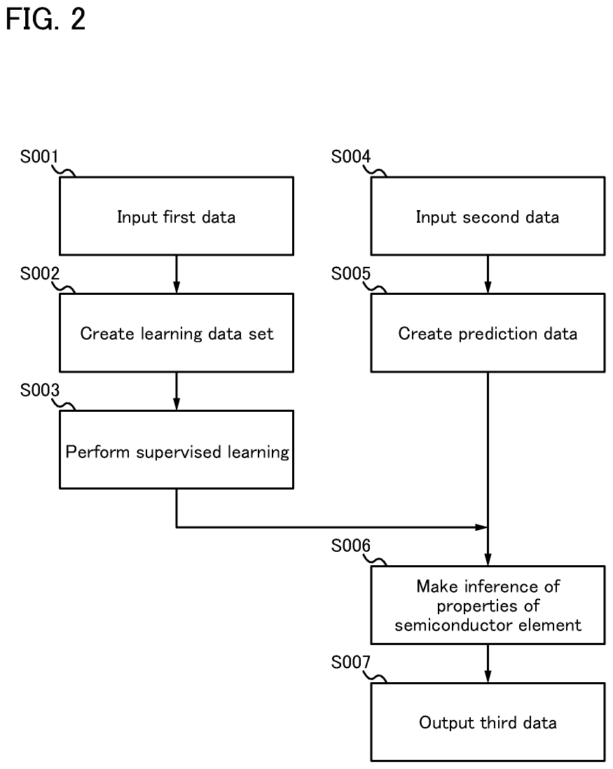

FIG. 2 is a flow chart showing the flow of processing executed by the property prediction system 100. That is, FIG. 2 can be regarded as a flow chart showing an example of a method for predicting the properties of a semiconductor element which is one embodiment of the present invention.

The method for predicting the properties of a semiconductor element includes Step S001 to Step S007. Step S001 to Step 003 are steps relating to learning of supervised learning, and Step S004 to Step S007 are steps relating to inference of supervised learning.

Step S001 is a step of inputting first data to the processing unit 102. The first data corresponds to the data IN1 described above. That is, the first data includes information on the semiconductor element 30_1 to the semiconductor element 30_m. Specifically, the first data includes the step list 10_1 to the step list 10_m and the properties 20_1 to the properties 20_m. Note that the first data may include information on the shapes of the semiconductor elements associated with the step lists ID of the step list 10_1 to the step list 10_m.

Step S002 is a step of creating a learning data set from the first data. Step S002 is performed in the processing unit 102 illustrated in FIG. 1A and FIG. 1B. The learning data set corresponds to the learning data set DS described above.

Step S002 includes a step of quantifying qualitative data included in the first data. The qualitative data is, for example, qualitative data on an apparatus or qualitative data on a material. Data obtained by quantification is included in the learning data set.

Step S003 is a step of performing learning of supervised learning on the basis of the learning data set. Step S003 is performed in the arithmetic unit 103 illustrated in FIG. 1A and FIG. 1B. For the algorithm (also referred to as a learning method) of the supervised learning, a neural network (especially, deep learning) is preferably used. Note that by learning of the supervised learning, a learned model for property prediction of a semiconductor element may be generated.

Step S004 is a step of inputting second data to the processing unit 102. The second data corresponds to the data IN2 described above. That is, the second data includes information on a semiconductor element specified by a user for property prediction of the semiconductor element. Specifically, the second data includes the step list 11.

In the case where the semiconductor element is manufactured in accordance with the step list 11, the second data sometimes includes information on the shape of the semiconductor element, the properties of the semiconductor element, or the like.

Note that Step S004 is preferably performed after steps up to Step S003 have been performed, but may be performed concurrently with Step S001 or may be performed while Step S001 to Step S003 are performed.

Step S005 is a step of creating data for property prediction of the semiconductor element from the second data. Step S005 is performed in the processing unit 102 illustrated in FIG. 1A and FIG. 1B. That is, the data for property prediction of the semiconductor element corresponds to the prediction data DI described above.

Step S005 includes a step of quantifying qualitative data included in the second data. The qualitative data is, for example, qualitative data on an apparatus or qualitative data on a material. Data obtained by quantification is included in the data for property prediction of the semiconductor element.

Note that Step S005 is preferably performed after steps up to Step S003 have been performed, but may be performed concurrently with Step S001 or may be performed while Step S001 to Step S003 are performed.

Step S006 is a step of making an inference of the properties of the semiconductor element from the data for property prediction of the semiconductor element on the basis of the learning results of supervised learning performed in Step S003. In other words, Step S006 is a step of making an inference of the properties of the semiconductor element from the data for property prediction of the semiconductor element using the learned model. Step S006 is performed in the arithmetic unit 103 illustrated in FIG. 1A and FIG. 1B.

Step S007 is a step of outputting third data. Step S007 is performed in the output unit 104 illustrated in FIG. 1A and FIG. 1B. The third data includes the inference results or information on the inference results.

In the above manner, the properties of the semiconductor element can be predicted. Instead of Step S007, a step of storing the inference results or information on the inference results in the storage unit 105 illustrated in FIG. 1A and the like may be performed. Alternatively, Step S007 is not necessarily performed.

Note that the steps (Step S001 to Step S003) relating to learning of supervised learning may be performed every time when information on a semiconductor element is stored in the memory unit 105, or may be performed regularly at predetermined timings (for example, once a day or once a week).

The method for predicting the properties of a semiconductor element is not limited to the above method. For example, the method for predicting the properties of a semiconductor element may include, after Step S003, a step of memorizing the learned model generated in Step S003. The learned model is stored in the storage unit 106 illustrated in FIG. 1B. When the learned model is generated in advance, Step S001 to Step S003 can be omitted in property prediction of a semiconductor element. Thus, the time needed for property prediction of a semiconductor element can be shortened.

### Neural Network

Here, a neural network that can be used for supervised learning will be described.

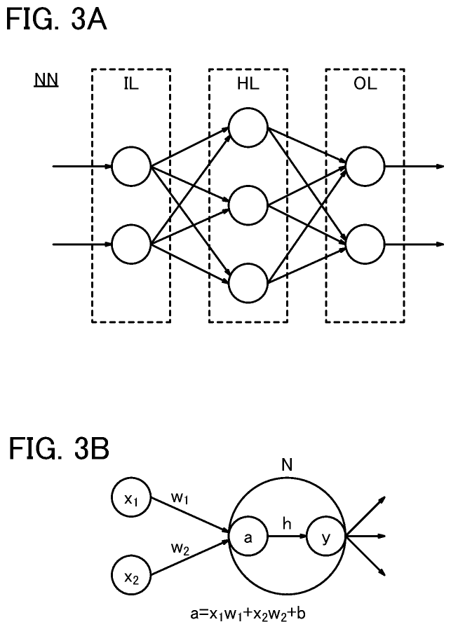

As illustrated in FIG. 3A, a neural network NN can be formed of an input layer IL, an output layer OL, and a hidden layer HL. The input layer IL, the output layer OL, and the hidden layer HL each include one or more neurons (units). Note that the hidden layer HL may be composed of one layer or two or more layers. A neural network including two or more hidden layers HL can also be referred to as a deep neural network (DNN). Learning using a deep neural network can also be referred to as deep learning.

Input data is input to neurons in the input layer IL. A signal output from a neuron in the previous layer or the subsequent layer is input to each neuron in the hidden layer HL. Output signals of the neurons in the previous layer are input to each neuron in the output layer OL. Note that each neuron may be connected to all the neurons in the previous and subsequent layers (full connection), or may be connected to some of the neurons.

FIG. 3B illustrates an example of an arithmetic operation with the neurons. Here, a neuron N and two neurons in the previous layer which output signals to the neuron N are illustrated. An output x₁ of one of the neurons in the previous layer and an output x₂ of the other of the neurons in the previous layer are input to the neuron N. Then, in the neuron N, a total sum x₁w₁+x₂w₂ of a multiplication result (x₁w₁) of the output x₁ and a weight w₁ and a multiplication result (x₂w₂) of the output x₂ and a weight w₂ is calculated, and then a bias b is added as necessary, so that the value a=x₁w₁+x₂w₂+b is obtained. Subsequently, the value a is converted with an activation function h, and an output signal y=ah is output from the neuron N. As the activation function h, for example, a sigmoid function, a tanh function, a softmax function, a ReLU function, a threshold function, or the like can be used.

In this manner, the arithmetic operation with the neurons includes the arithmetic operation that sums the products of the outputs and the weights of the neurons in the previous layer, that is, the product-sum operation (x₁w₁+x₂w₂ described above). This product-sum operation may be performed using a program on software or may be performed using hardware. In the case where the product-sum operation is performed using hardware, a product-sum operation circuit can be used. Either a digital circuit or an analog circuit can be used as this product-sum operation circuit. In the case where an analog circuit is used as the product-sum operation circuit, the circuit scale of the product-sum operation circuit can be reduced, or higher processing speed and lower power consumption can be achieved by reduced frequency of access to a memory.

The product-sum operation circuit may be formed using a transistor containing silicon (such as single crystal silicon) in a channel formation region (hereinafter, also referred to as a Si transistor) or may be formed using a transistor including an oxide semiconductor in a channel formation region (hereinafter, also referred to as an OS transistor). An OS transistor is particularly suitable for a transistor included in an analog memory of the product-sum operation circuit because of its extremely low off-state current. Note that the product-sum operation circuit may be formed using both a Si transistor and an OS transistor.

In the case where the product-sum operation is performed using hardware, a product-sum operation circuit is preferably included in the arithmetic unit 103 that is included in the property prediction system 100.

The above is the description of the neural network. Note that in one embodiment of the present invention, deep learning is preferably used. That is, a neural network including two or more hidden layers HL is preferably used.

The above is the description of an example of the method for predicting the properties of a semiconductor element.

### Detail of Method for Predicting Properties of Semiconductor Element

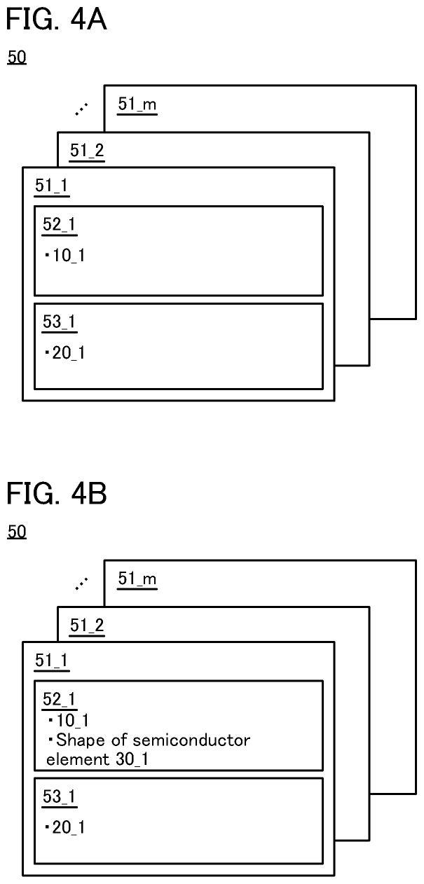

A method for predicting the properties of a semiconductor element will be described in detail below with reference to FIG. 4A to FIG. 7B.

### Structure of Semiconductor Element

First, a structure of a semiconductor element will be described. A transistor is described here as an example of the semiconductor element.

Transistors are classified into various types depending on the positional relationship, shapes, and the like of the components. For example, transistor structures may be classified into a bottom-gate structure and a top-gate structure depending on the positional relationship among a substrate, a gate, and a channel formation region. A transistor structure in which a gate is provided between a channel formation region and a substrate is called a bottom-gate structure. In contrast, a transistor structure in which a channel formation region is provided between a gate and a substrate is called a top-gate structure.

Furthermore, transistor structures are classified into a bottom-contact structure and a top-contact structure depending on the connection portions of a source and a drain with a semiconductor layer where a channel is formed. A transistor structure in which a source and a drain are connected to a semiconductor layer where a channel is formed on the substrate side is called a bottom-contact structure. A transistor structure in which a source and a drain are connected to a semiconductor layer where a channel is formed on the opposite side of the substrate is called a top-contact structure.

That is, transistor structures are classified into a BGBC (bottom-gate bottom-contact) structure, a BGTC (bottom-gate top-contact) structure, a TGTC (top-gate top-contact) structure, and a TGBC (top-gate bottom-contact) structure.

Examples of transistor structures other than the above four structures include a dual-gate structure in which gates are provided over and below a semiconductor layer, and a TGSA (Top-Gate Self-Align) structure in which a source and a drain are formed in a self-aligned manner with respect to the pattern of a gate.

In the semiconductor element 30_1 to the semiconductor element 30_m, the structures of the semiconductor elements are preferably the same or similar to each other. For example, in the case where the semiconductor element 30_1 to the semiconductor element 30_m are transistors, the structures of the semiconductor element 30_1 to the semiconductor element 30_m are preferably a BGBC structure, a BGTC structure, a TGTC structure, a TGBC structure, a dual-gate structure, or a TGSA structure. When the semiconductor elements have the same structure, the accuracy of property prediction of a semiconductor element can be improved.

Note that in the semiconductor element 30_1 to the semiconductor element 30_m, the semiconductor elements may have difference structures. In the case where the semiconductor element 30_1 to the semiconductor element 30_m are transistors, some of the semiconductor element 30_1 to the semiconductor element 30_m may have a TGTC structure and the others may have a TGSA structure. Combination of a plurality of structures allows versatile property prediction of a semiconductor element.

The above is the description of the structure of a semiconductor element.

### Properties of Semiconductor Element

Next, the properties of a semiconductor element will be described.

In this specification and the like, the properties of a semiconductor element refer to the electrical characteristics of the semiconductor element. Examples of the properties of a semiconductor element include drain current (Id)—gate voltage (Vg) characteristics, drain current (Id)—drain voltage (Vd) characteristics, and capacitor (C)—gate voltage (V) characteristics.

The properties of a semiconductor element may be results obtained by a reliability test. Examples of the results obtained by a reliability test include change in an on-state current (Ion) over time (also referred to as stress time dependence of Ion) and change in ΔVsh over time (also referred to as stress time dependence of ΔVsh).

Note that ΔVsh is the amount of change in a shift voltage (Vsh). Here, in a drain current (Id)—gate voltage (Vg) curve of a transistor, the shift voltage (Vsh) is defined as Vg at the intersection point of the tangent, which has the maximum slope on the curve, with the straight line of Id=1 pA.

Examples of the reliability test include a +GBT (Gate Bias Temperature) stress test, a +DBT (Drain Bias Temperature) stress test, a −GBT stress test, a +DGBT (Drain Gate Bias Temperature) stress test, a +BGBT (Back Gate Bias Temperature) stress test, and a −BGBT stress test.

Since measurement is sometimes performed for a long time in a reliability test, it takes time to obtain the results of the reliability test. In addition, a measurement apparatus is occupied during the measurement. In view of this, with the use of the property prediction system for a semiconductor element which is one embodiment of the present invention, the results of the reliability test can be predicted. Accordingly, whether or not to conduct the reliability test can be determined on the basis of the prediction results, whereby some reliability tests can be omitted. Alternatively, the priority of the reliability tests can be determined. Thus, a measurement apparatus can be efficiently used.

In this specification and the like, the properties of a semiconductor element include property values calculated from the measurement results of the electrical characteristics of the semiconductor element. Examples of the property values include a threshold voltage (Vth), Vsh, a subthreshold swing value (S value), Ion, and a field-effect mobility (μFE). The subthreshold swing value (S value) refers to the amount of change in a gate voltage which makes the drain current change by one digit in a subthreshold region at a constant drain voltage. The property values calculated from the measurement results of the electrical characteristics of the semiconductor element are referred to as property values of the semiconductor element or simply property values below.

In addition, the properties of a semiconductor element also include temperature characteristics. Examples of the temperature characteristics include temperature characteristics of the threshold voltage and the temperature dependence of capacitor characteristics. Since the temperature characteristics need to be measured at different temperatures, it takes time to evaluate the temperature characteristics. With the use of the property prediction system for a semiconductor element which is one embodiment of the present invention, the temperature characteristics can be predicted without fabricating a semiconductor element and performing measurement for evaluating the temperature characteristics.

In the case where the properties of a semiconductor element are property values, the properties of the semiconductor element are stored in the memory unit 105 as numerical data. In the case where the properties of a semiconductor element are electrical characteristics or temperature characteristics, the properties of the semiconductor element are stored in the memory unit 105 as bivariate data. That is, the properties of a semiconductor element stored in the memory unit 105 are quantified.

For example, in the case where the properties of a semiconductor element are change in ΔVsh over time obtained by a reliability test, a data set relating to time and ΔVsh is stored in the memory unit 105. In the case where the properties of a semiconductor element are the Id-Vg characteristics, a data set relating to Vg and Id is stored in the memory unit 105.

The above is the description of the properties of a semiconductor element.

### Learning Data Set

Here, a learning data set for learning of supervised learning will be described.

FIG. 4A and FIG. 4B are diagrams illustrating structures of a learning data set 50. The learning data set 50 corresponds to the learning data set DS generated in the processing unit 102. The learning data set 50 includes learning data 51_1 to learning data 51_m. The learning data 51_i (i is an integer of greater than or equal to 1 and less than or equal to m) includes input data 52_i and training data 53_i. Note that the learning data 51_i includes information on the semiconductor element 30_i.

The learning data set 50 is generated from the data IN1 that is input to the processing unit 102 illustrated in FIG. 1A and FIG. 1B. Thus, the learning data set 50 is generated by performing extraction, processing, conversion, selection, removal, or the like on data included in the data IN1.

In this embodiment, training data is the properties of a semiconductor element among information on the semiconductor element. That is, a target to be predicted in this embodiment is the properties of a semiconductor element.

In this embodiment, the input data is preferably created from the step list of a semiconductor element among information on a semiconductor device. That is, the input data preferably includes part of the step list of the semiconductor element among information on the semiconductor device. The properties of a semiconductor element to be predicted are affected by the kind of a semiconductor material used for a layer where a channel is formed, the kind of a conductive material used for a layer functioning as a gate electrode, the kind of an insulating material used for a layer functioning as a gate insulating film, the thicknesses of these layers, the formation conditions of these layers, and the like. Note that the kind of a material used for a layer, the thickness of a layer, the formation conditions of a layer, and the like are included in the step list of the semiconductor element. Thus, the input data is preferably created from the step list of the semiconductor element.

Data included in the learning data set for supervised learning is preferably quantitative data. In other words, the data is preferably quantified. As compared with the case where the learning data set includes data (qualitative data) other than a numerical value, in the case where the data included in the learning data set is quantified, a machine learning model can be prevented from being complicated.

In the learning data set 50 illustrated in FIG. 4A, the input data 52_1 to the input data 52_m are created from the step list 10_1 to the step list 10_m, respectively. The training data 53_1 to the training data 53_m are created from the properties 20_1 to the properties 20_m, respectively.

As illustrated in FIG. 4B, the input data 52_1 to the input data 52_m may be created from the step list 10_1 to the step list 10_m and information on the shapes of the semiconductor element 30_1 to the semiconductor element 30_m, respectively. By adding the information on the shapes of the semiconductor element 30_1 to the semiconductor element 30_m to the input data 52_1 to the input data 52_m, the accuracy of property prediction of a semiconductor element can be improved.

It is preferable that the step list 10_1 to the step list 10_m each include the same number of steps. This makes it easy to create a learning data set or prediction data. At the time of creating the learning data set or the prediction data, selection is performed on the step list. For example, part of the step list is extracted or another part of the step list is removed. Thus, the step list 10_1 to the step list 10_m may include different number of steps.

As described above, the properties 20_1 to the properties 20_m are quantified data and thus can be included in the training data 53_1 to the training data 53_m without through particular conversion.

In the case where the properties 20_1 to the properties 20_m are bivariate data, one or more characteristic points may be extracted from the bivariate data to be included in the training data 53_1 to the training data 53_m. A plurality of points may be extracted from the bivariate data such that the values of one of the two variables are at regular intervals and included in the training data 53_1 to the training data 53_m.

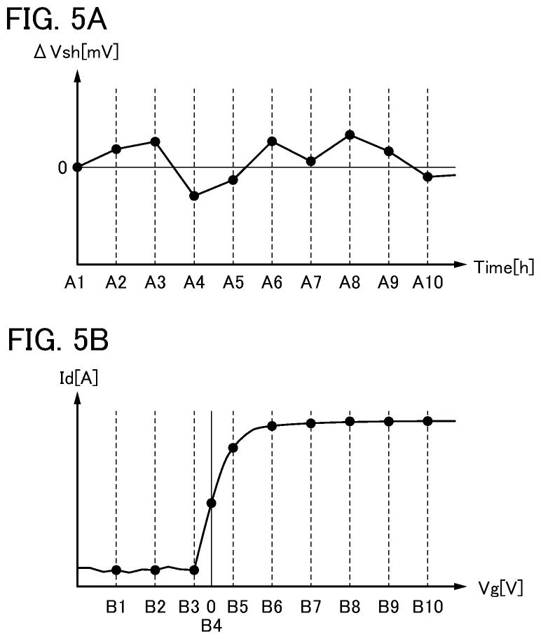

FIG. 5A is a diagram showing results obtained by a reliability test of a semiconductor element. In FIG. 5A, the horizontal axis represents time elapsed from the beginning of the measurement (also referred to as stress time) [h], and the vertical axis represents ΔVsh [mV]. For example, Time A1 to Time A10 and values of ΔVsh from Time A1 to Time A10 are preferably extracted to be used as training data.

The values of ΔVsh may be characteristic at some or all of Time A1 to Time A10. Time A1 to Time A10 may have regular intervals. Alternatively, some of Time A1 to Time A10 may each have a first interval and the others of Time A1 to Time A10 may each have a second interval different from the first interval.

The number of sets of extracted time and value of ΔVsh at the time is not limited to 10, and may be greater than or 1 and less than or equal to 9 or may be greater than or equal to 11.

FIG. 5B is a diagram showing the Id-Vg characteristics of a semiconductor element. In the Id-Vg curve, a drain current value at a gate voltage of 0 V is one of the characteristic points. The gate voltage is a voltage B4, for example. As voltages lower than the voltage B4, a voltage B1 to a voltage B3 are specified. As voltages higher than the voltage B4, a voltage B5 to a voltage B10 are specified. For example, the voltage B1 to the voltage B10 and drain current values at the voltage B1 to the voltage B10 are preferably extracted to be used as training data. Alternatively, one of the voltage B1 to the voltage B10 except for the voltage B4 may be set 0 V.

The number of sets of extracted voltage and drain current value at the voltage is not limited to 10, and may be greater than or 1 and less than or equal to 9 or may be greater than or equal to 11.

### Method for Creating Input Data

Here, a method for creating the input data 52_1 to the input data 52_m illustrated in FIG. 4A will be described.

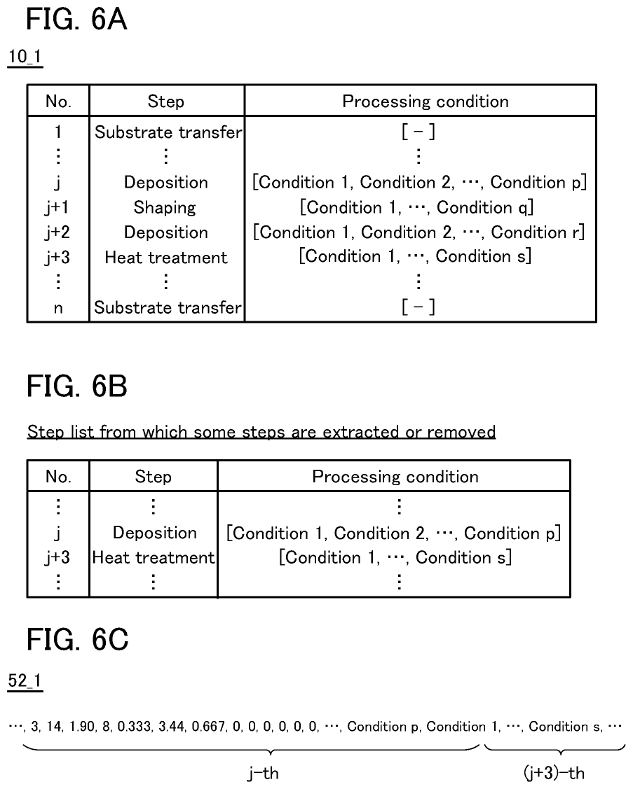

First, a method for creating the input data 52_1 will be described. Here, an example in which the input data 52_1 is created from the step list 10_1 will be described with reference to FIG. 6A to FIG. 6C.

In a step list, a plurality of steps are set in the order of manufacturing steps of a semiconductor element. Examples of the steps for manufacturing a semiconductor element include steps of deposition, cleaning, resist application, light exposure, development, shaping, heat treatment, testing, and substrate transfer.

Furthermore, processing conditions are specified for each of the plurality of steps set in the step list. Examples of the processing conditions in the deposition step include an apparatus, a material, a film thickness, a temperature, a pressure, a power, and a flow rate. Note that the processing conditions of the deposition step might affect the properties of the semiconductor element. In addition, steps other than the deposition step might also affect the properties of the semiconductor element depending on the processing conditions, the presence or absence of the steps, the order of the steps, and the like.

Qualitative data and quantitative data are both included as the processing conditions, and values are determined by various scales. For example, to express similarity between feature values in the steps, qualitative data on a material is preferably converted into quantitative data such as physical properties for each material and the set of the physical properties is preferably handled as the feature values.

Here, the step list 10_1 includes n steps (n is an integer of 2 or more). For example, in the step list 10_1 shown in FIG. 6A, a first step is a substrate transfer step, a j-th step (j is an integer greater than or equal to 2 and less than or equal to (n−4)) is a deposition step, a (j+1)-th step is a shaping step, a (j+2)-th step is a deposition step, a (j+3)-th step is a heat treatment step, and an n-th step is a substrates transfer step. Note that “No.” indicated in FIG. 6A and FIG. 6B is a step number.

The processing conditions specified in the j-th step (deposition step) are Condition 1 to Condition p (p is an integer of 2 or more). The processing conditions specified in the (j+1)-th step (shaping step) are Condition 1 to Condition q (q is an integer of 1 or more). The processing conditions specified in the (j+2)-th step (deposition step) are Condition 1 to Condition r (r is an integer of 2 or more). The processing conditions specified in the (j+3)-th step (heat treatment step) are Condition 1 to Condition s (s is an integer of 1 or more).

First, some steps are extracted from the n steps included in the step list 10_1. The extracted steps are, for example, steps estimated to make a large contribution to the properties of a semiconductor element. The extracted steps are, for example, steps having many changes in conditions. Extracting some steps included in the step list 10_1 can reduce the number of intermediate variables in machine learning. In other words, the number of neurons included in an input layer can be reduced in supervised learning using a neural network. This can optimize the number of hidden layers and the number of neurons in the hidden layers, thereby reducing the calculation amount or calculation time of learning or inference. Furthermore, overtraining can be prevented in some cases.

For example, in the case where the processing conditions specified in the j-th step (deposition step) are often changed among the step list 10_1 to the step list 10_m, the j-th step (deposition step) is preferably extracted from the step list 10_1. For example, in the case where the (j+3)-th step (heat treatment step) is estimated to make a large contribution to the properties of a semiconductor element, the (j+3)-th step (heat treatment step) is preferably extracted from the step list 10_1.

Alternatively, some steps different from the above steps may be removed from the n steps included in the step list 10_1. The removed steps are, for example, steps estimated to make a small contribution to the properties of a semiconductor element. Alternatively, the removed steps are, for example, steps having no change in processing conditions. Removal of some steps different from the above steps can reduce the number of intermediate variables in machine learning. In other words, the number of neurons included in an input layer can be reduced in supervised learning using a neural network. This can optimize the number of hidden layers and the number of neurons in the hidden layers, thereby reducing the calculation amount or calculation time of learning or inference. Furthermore, overtraining can be prevented in some cases.

For example, the substrate transfer steps (the first step and the n-th step) are estimated not to affect the properties of a semiconductor element. Thus, the substrate transfer steps (the first step and the n-th step) are preferably removed from the step list 10_1. In the case where the processing conditions specified in the (j+1)-th step (shaping step) and the processing conditions specified in the (j+2)-th step (deposition step) are the same in the step list 10_1 to the step list 10_m, for example, the (j+1)-th step (shaping step) and the (j+2)-th step (deposition step) are preferably removed from the step list 10_1.

In the above manner, some steps are extracted from the step list 10_1. Alternatively, some steps different from the above steps are removed from the step list 10_1. FIG. 6B shows an example in which the j-th step, the (j+3)-th step, and the like are extracted. Note that the example shown in FIG. 6B can also be regarded as a case where the first step, the (j+1)-th step, the (j+2)-th step, the n-th step, and the like are removed.

Next, data on the processing conditions included in the step list 10_1 from which some steps are removed or the step list 10_1 from which some steps different from the above some steps are removed are quantified.

As described above, examples of the processing conditions in the deposition step include an apparatus, a material, a film thickness, a temperature, a pressure, a power, and a flow rate. Since a film thickness, a temperature, a pressure, a power, a flow rate, and the like are set as values, these processing conditions are quantified data. Thus, these processing conditions can be included in the input data 52_1 without through particular conversion.

The set values of the processing conditions preferably have the same unit. When the unit is the same, the amount of data included in the learning data set 50 can be reduced. Thus, the time spent for data transmission and reception, learning, inference, or the like can be reduced.

Data on an apparatus is included in a step list as qualitative data in some cases. Examples of qualitative data on an apparatus include the apparatus name (including abbreviation and called name) and a method used in the apparatus.

Data on a material is included in a step list as qualitative data in some cases. Examples of qualitative data on a material include the material name (including abbreviation and called name) and the compositional formula.

As described above, the data included in a learning data set used for supervised learning is preferably quantified. Thus, the qualitative data included in the step list is preferably quantified.

### Quantification of Qualitative Data on Apparatus

Here, quantification of qualitative data on an apparatus will be described. Note that the description is made using an example in which an apparatus name that is qualitative data on an apparatus is input as Condition 1 of the deposition step.

Examples of the deposition apparatus include an apparatus capable of deposition using a chemical vapor deposition (CVD) method (sometimes also referred to as a CVD apparatus), an apparatus capable of deposition using a sputtering method (sometimes also referred to as a sputtering apparatus), and an apparatus capable of deposition using an atomic layer deposition (ALD) method (sometimes also referred to as an ALD apparatus).

Note that the CVD method can be classified into a plasma enhanced CVD (PECVD) method using plasma, a thermal CVD (TCVD) method using heat, a photo CVD method using light, and the like. Thus, a CVD apparatus used in the CVD method differs depending on the method in some cases. That is, a plurality of CVD apparatuses are prepared in some cases. The same is applied to a sputtering apparatus, an ALD apparatus, and the like.

The data on an apparatus (the apparatus name here) input as the processing condition is qualitative data. Thus, Label Encoding is preferably used for quantifying the qualitative data on an apparatus. For example, the apparatus name is preferably managed with an ID. An ID different from the step list ID is preferably assigned to the apparatus name. Here, the ID assigned to the apparatus name is referred to as an apparatus ID.

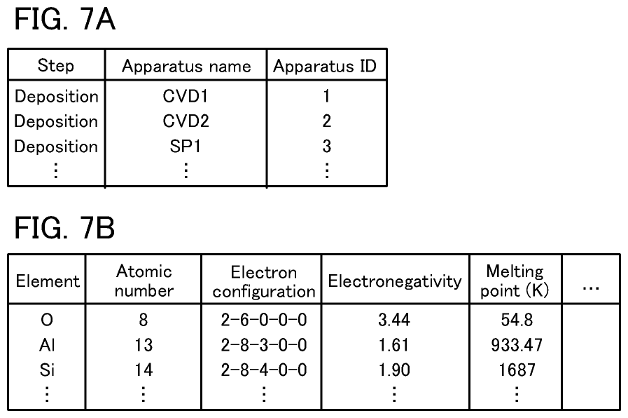

FIG. 7A shows a correspondence table between the apparatus name and the apparatus ID. For example, in the case where the apparatus name is CVD1, the apparatus ID is 1. In the case where the apparatus name is CVD2, the apparatus ID is 2. In the case where the apparatus name is SP1, the apparatus ID is 3. By converting the apparatus name into the apparatus ID, the apparatus name can be handled as numerical data.

The correspondence table is preferably stored in the memory unit 105. It is also preferable that a new apparatus name and an apparatus ID associated with the new apparatus name be added to the correspondence table through the input unit 101, a memory medium, communication, or the like, every time when the number of usable apparatuses increases.

Although the method for quantifying the qualitative data on an apparatus using Label Encoding is described above, the method for quantifying the qualitative data on an apparatus is not limited thereto. One-hot Encoding (also referred to as 1 of K Encoding) may be used for quantifying the qualitative data on an apparatus.

For example, in the case where the number of apparatuses that can be used in a deposition step is t (t is an integer of 1 or more), the apparatus name is preferably expressed using a t-dimensional One-hot vector. When the number of apparatuses that can be used in the steps is not large, a lower-dimensional vector can be used for expression. In this case, the calculation amount or calculation time of learning or inference can be reduced.

As the method for quantifying the qualitative data on an apparatus other than the above, Target Encoding may be used, for example.

The above is the description of quantification of the qualitative data on an apparatus.

### Quantification of Qualitative Data on Material

Here, quantification of qualitative data on a material will be described. Note that the description is made using an example in which the material name (including abbreviation, called name, or the like) that is qualitative data on a material is input as Condition 2 of the deposition step. The material is an inorganic material.

The crystal structure, film quality, or the like of a material used for a semiconductor element changes depending on the processing conditions. Furthermore, the change also depends on a material used for a formed film, roughness of a formation surface, or the like. Thus, in the case where the material name that is qualitative data is converted into the physical properties (crystal structure, density, permittivity, or the like) of the material which are quantitative data using a database or the like, the accuracy of property prediction of a semiconductor element might decrease. In view of this, in this embodiment, the qualitative data on a material (here, the material name) is converted into a constituent element and a composition.

First, the material name is converted into a compositional formula. For example, in the case where “silicon oxide” is input as Condition 2 in the deposition step, “silicon oxide” is preferably converted into “SiO₂”. For conversion of the material name into the compositional formula, a concept dictionary or a database may be used or a correspondence table between the material name and the compositional formula created in advance may be used.

Next, the compositional formula is converted into constituent elements and a composition. For example, in the case where a material contains an element M1, an element M2, an element M3, and an element M4 with a composition of M1:M2:M3:M4=w:x:y:z, the compositional formula is converted into “M1, M2, M3, M4, w:x:y:z” or “M1, w, M2, x, M3, y, M4, z”.

Note that the composition is preferably normalized. For example, the composition is preferably normalized such that w+x+y+z=1 is satisfied. Accordingly, materials having the same combination of constituent elements with different compositions can be distinguished from each other.

In the case where a material contains one kind of element, M2, M3, M4, x, y, and z are each preferably described as zero. Similarly, in the case where a material contains two kinds of elements, M3, M4, y, and z are each preferably described as zero. In the case where a material contains three kinds of elements, M4 and z are each preferably described as zero.

Specifically, in the case where the compositional formula is “SiO₂”, “SiO₂” is converted into “Si, O, 0, 0, 0.333:0.667:0:0” or “Si, 0.333, O, 0.667, 0, 0, 0, 0”.

Although the number of elements and the composition are described above so that they can be applied to a material containing four or less kinds of constituent elements, one embodiment of the present invention is not limited thereto. For example, the number of elements and the composition may be described so that they can be applied to a material containing five or more kinds of constituent elements. Alternatively, for example, in the case where a material used for a semiconductor element contains three or less kinds of constituent elements, the compositional formula may be converted into “M1, M2, M3, w:x:y” or “M1, w, M2, x, M3, y”. This can reduce the number of intermediate variables in machine learning. This can optimize the number of hidden layers and the number of neurons in the hidden layers, thereby reducing the calculation amount or calculation time of learning or inference.

Then, the element is converted into the properties of the element. Examples of the properties of the element include the atomic number, the group, the period, the electron configuration, the atomic weight, the atomic radius, the atomic volume, the electronegativity, the ionized energy, the electron affinity, the dipole polarizability, the elemental melting point, the elemental boiling point, the elemental lattice constant, the elemental density, and the elemental heat conductivity. The atomic radius is preferably one or more selected from the covalent bond radius, the Van der Waals force radius, the ionic radius, and the metal bond radius.

In particular, the electronegativity and the atomic number or the electron configuration are preferably selected as the properties of the element to be converted. In the case where a material contains one kind of element, the characteristics of the material is likely to appear in the atomic number and electronegativity. In the case where the material contains two or more kinds of elements, the electronegativity is likely to appear in the coupling form between different elements. For example, between elements having similar electronegativities, covalent bonding or metal bonding is dominant. Meanwhile, between elements having greatly different electronegativities, ionic bonding is dominant.

FIG. 7B shows an example of a corresponding table between an element and the properties of the element. In FIG. 7B, the atomic number, the electron configuration, the electronegativity, the elemental melting point (K), and the like are included as the properties of the element. For conversion of the element into the properties of the element, a database may be used, or a correspondence table between the element and the properties of the element created in advance may be used.

Specifically, in the case where the atomic number and the electronegativity are selected as the properties of the element, “Si” is converted into “14, 1.90”. In addition, “O” is converted into “8, 3.44”.

In the above manner, “silicon oxide” input as Condition 2 in the deposition step can be converted into “14, 1.90, 8, 3.44, 0, 0, 0, 0, 0.333:0.667:0:0” or “14, 1.90, 0.333, 8, 3.44, 0.667, 0, 0, 0, 0, 0, 0”. Accordingly, the qualitative data on a material can be quantified.

As described above, the properties of a semiconductor element can be predicted in the first-principles manner. Even in the case of using a material that has not been used for a semiconductor element, the properties of the semiconductor element can be predicted without a decrease in accuracy. Furthermore, even in the case of using a material that is not described in a database or the like for a semiconductor element, the properties of the semiconductor element can be predicted without a decrease in accuracy.

Note that the material name may be directly converted into constituent elements and a composition without through a compositional formula.

The above is the description of quantification of the qualitative data on material.

In the above manner, the input data 52_1 composed of quantified data as shown in FIG. 6C can be created. Specifically, the input data 52_1 includes data on the processing conditions shown in FIG. 6C. Note that the input data 52_1 may include the step number.

The order of the step of performing selection (extraction or removal) on the step list and the step of converting qualitative data into quantitative data is not limited to the above. For example, qualitative data may be converted into quantitative data and then selection (extraction or removal) may be performed on the step list so that the input data 52_1 is created from the step list 10_1.

In the above manner, the learning data 51_1 including quantified data can be generated. Note that the learning data 51_2 to the learning data 51_m have a structure similar to that of the learning data 51_1. That is, the learning data 51_2 to the learning data 51_m can be generated by the above method.

FIG. 4A shows a case where the input data 52_1 to the input data 52_m are created from the step list 10_1 to the step list 10_m, respectively; however, one embodiment of the present invention is not limited thereto. For example, as shown in FIG. 4B, the input data 52_1 to the input data 52_m may be created from the step list 10_1 to the step list 10_m and information on the shapes of the semiconductor element 30_1 to the semiconductor element 30_m, respectively.

The input data 52_1 to the input data 52_m may be created from the step list 10_1 to the step list 10_m and first properties of the semiconductor element 30_1 to the semiconductor element 30_m, respectively, and the training data 53_1 to the training data 53_m may be created from second properties of the semiconductor element 30_1 to the semiconductor element 30_m, respectively.

In the above, the first property and the second property are made different from each other. For example, the first property is a property value of a semiconductor element and the second property is the result of a reliability test of the semiconductor element. Since the reliability of a semiconductor element is affected by a lot of factors and the factors relate to each other complicatedly, prediction with experiences is difficult. Thus, the reliability of a semiconductor element is a suitable target to be estimated. In addition, the property values of the semiconductor element indirectly include information such as the manufacturing process of the semiconductor element. Thus, by adding property values of the semiconductor element to the input data, the information is supplied for supervised learning and the accuracy of property prediction of a semiconductor element can be improved.

Note that the learning data set 50 may be composed of only data on semiconductor elements having the same or similar structures. In other words, the learning data set 50 may be created for each semiconductor element structure. This can improve the accuracy of property prediction of a semiconductor element. The learning data set 50 may be composed of data on semiconductor elements regardless of the structure. This enables versatile property prediction of a semiconductor element.

The above is the description of the learning data set. The use of the input data and the training data for the training of a machine learning model enables property prediction of a semiconductor element.

### Data for Property Prediction of Semiconductor Element

Here, data for property prediction of a semiconductor element will be described.

Data for property prediction of a semiconductor element is created from the data IN2 that is input to the processing unit 102 illustrated in FIG. 1A and FIG. 1B. Thus, the data for property prediction of a semiconductor element is created by performing extraction, processing, conversion, selection, removal, or the like on data included in the data IN2.

The data IN2 includes at least information on a semiconductor element. Note that the data IN2 sometimes includes the properties or the like of a semiconductor element.

Note that the data for property prediction of a semiconductor element preferably has a structure similar to that of the input data of the learning data. For example, in the case where the input data 52_1 to the input data 52_m are created from the step list 10_1 to the step list 10_m, respectively, the data for property prediction of a semiconductor element is preferably created from the step list 11. Alternatively, for example, in the case where the input data 52_1 to the input data 52_m are created from the step list 10_1 to the step list 10_m and the properties of the semiconductor element 30_1 to the semiconductor element 30_m, respectively, the data for property prediction of a semiconductor element is preferably created from the step list 11 and the properties of the semiconductor element associated with the step list ID of the step list 11.

The above is the description of the data for property prediction of a semiconductor element.

According to one embodiment of the present invention, the properties of a semiconductor element can be predicted without using the physical properties or the like of a material contained in the semiconductor element. Furthermore, the use of the previous experiment data enables the semiconductor element structure to be optimized at high speed by virtual screening. Even if it seems to be difficult to perform interpolation when a person sees data, sometimes it can be regarded as being possible to perform interpolation owing to a nonlinear or high-order expression by a machine learning model. Furthermore, when the expression obtained by the machine learning model is cut out fragmentarily and studied, the regularity that has not been found can be seen.

### Computer Device

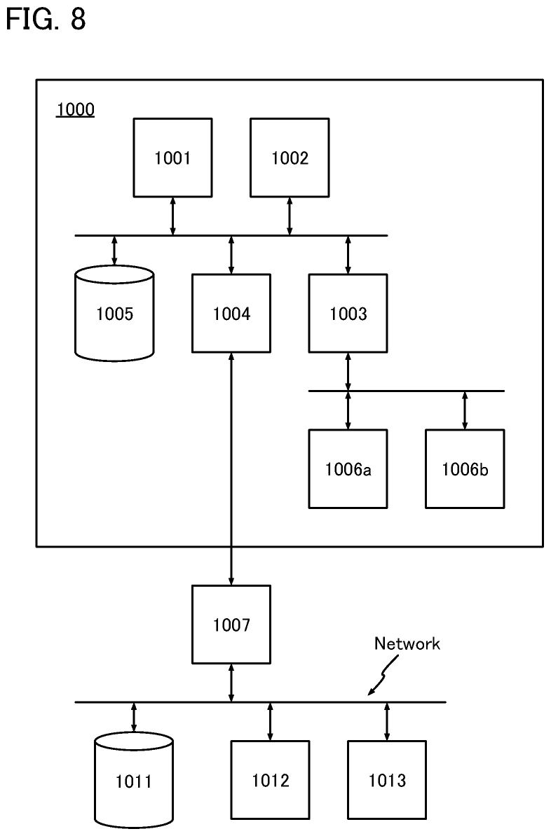

In this section, a computer device including the property prediction system for a semiconductor element which is one embodiment of the present invention is described with reference to FIG. 8.

FIG. 8 is a diagram illustrating a computer device including the property prediction system for a semiconductor element. A computer device 1000 includes an arithmetic device 1001, a memory 1002, an input/output interface 1003, a communication device 1004, and a storage 1005. The computer device 1000 is electrically connected to a display device 1006a and a keyboard 1006b through the input/output interface 1003.

The computer device 1000 may be an information processing device such as a personal computer used by a user. In this case, the arithmetic device 1001 includes the processing unit 102 and the arithmetic unit 103 illustrated in FIG. 1A and FIG. 1B. The storage 1005 includes the memory unit 105 and/or the storage unit 106 illustrated in FIG. 1A and FIG. 1B. The display device 1006a corresponds to the output unit 104 illustrated in FIG. 1A and FIG. 1B. The keyboard 1006b corresponds to the input unit 101 illustrated in FIG. 1A and FIG. 1B.

A learned model may be stored in the memory 1002 or may be stored in the storage 1005.

The computer device 1000 may be connected to a database 1011, a remote computer 1012, and a remote computer 1013 via a network (Network). The computer device 1000 is electrically connected to a network interface 1007 through the communication device 1004. The network interface 1007 is electrically connected to the database 1011, the remote computer 1012, and the remote computer 1013 via the network (Network).

Here, examples of the network include a local area network (LAN) and the Internet. In addition, either one or both of wired and wireless communications can be used for the network. Furthermore, in the case where a wireless communication is used for the network, besides near field communication means such as Wi-Fi (registered trademark) and Bluetooth (registered trademark), a variety of communication means such as the third generation mobile communication system (3G)-compatible communication means, LTE (sometimes also referred to as 3.9G)-compatible communication means, the fourth generation mobile communication system (4G)-compatible communication means, or the fifth generation mobile communication system (5G)-compatible communication means can be used.

As described above, the processing unit of the property prediction system for a semiconductor element may be provided in a server to be accessed by a client PC via a network and used. For example, the computer device 1000 can be regarded as the client PC and the remote computer 1012 and/or the remote computer 1013 can be regarded as the server.

In this case, the processing unit 102 and the arithmetic unit 103 illustrated in FIG. 1A and FIG. 1B are provided in the remote computer 1012 and/or the remote computer 1013. That is, the arithmetic device included in the remote computer 1012 and/or the remote computer 1013 includes the processing unit 102 and the arithmetic unit 103. In addition, the database 1011 includes the memory unit 105 and/or the storage unit 106 illustrated in FIG. 1A and FIG. 1B.

As described above, one embodiment of the present invention can provide a property prediction system for a semiconductor element. Another embodiment of the present invention can provide a method for predicting the properties of a semiconductor element. Another embodiment of the present invention can provide a learning data set for property prediction of a semiconductor element.

Parts of this embodiment can be combined as appropriate for implementation.

### REFERENCE NUMERALS

IN1: data, IN2: data, 10: a plurality of step lists, 10_m: step list, 10_1: step list, 11: step list, 20: a plurality of properties, 20_m: properties, 20_1: properties, 30: a plurality of semiconductor elements, 30_i: semiconductor element, 30_m: semiconductor element, 30_1: semiconductor element, 50: learning data set, 51_i: learning data, 51_m: learning data, 51_1: learning data, 51_2: learning data, 52_i: input data, 52_m: input data, 52_1: input data, 53_i: training data, 53_m: training data, 53_1: training data, 100: property prediction system, 101: input unit, 102: processing unit, 103: arithmetic unit, 104: output unit, 105: memory unit, 106: storage unit, 1000: computer device, 1001: arithmetic device, 1002: memory, 1003: input/output interface, 1004: communication device, 1005: storage, 1006a: display device, 1006b: keyboard, 1007: network interface, 1011: database, 1012: remote computer, 1013: remote computer

1. A property prediction system for a semiconductor element, the property prediction system performing learning of supervised learning on the basis of a learning data set and making an inference of properties of a semiconductor element from prediction data on the basis of a result of the learning,
wherein the property prediction system for a semiconductor element comprises a memory unit, an input unit, a processing unit, and an arithmetic unit,
wherein the processing unit is configured to create the learning data set from first data stored in the memory unit;
wherein the processing unit is configured to create the prediction data from second data supplied from the input unit;
wherein the processing unit is configured to convert qualitative data into quantitative data; and
wherein the processing unit is configured to perform extraction or removal on the first data and the second data,
wherein the first data comprises step lists of a first semiconductor element to an m-th semiconductor element (m is an integer of 2 or more) and properties of the first semiconductor element to the m-th semiconductor element,
wherein the second data comprises a step list of an (m+1)-th semiconductor element,
wherein the qualitative data is a material name or a compositional formula,
wherein the quantitative data is properties of an element and a composition, and
wherein the arithmetic unit is configured to perform learning and inference of the supervised learning.

2. The property prediction system for a semiconductor element, according to claim 1,
wherein properties of the element are any one or more of an atomic number, a group, a period, an electron configuration, an atomic weight, an atomic radius (a covalent bond radius, a Van der Waals force radius, an ionic radius, or a metal bond radius), an atomic volume, an electronegativity, an ionized energy, an electron affinity, a dipole polarizability, an elemental melting point, an elemental boiling point, an elemental lattice constant, an elemental density, and an elemental heat conductivity.

3. The property prediction system for a semiconductor element, according to claim 1,
wherein the properties of the semiconductor element are change in ΔVsh over time obtained by a reliability test (a +GBT stress test, a +DBT stress test, a −GBT stress test, a +DGBT stress test, a +BGBT stress test, or a −BGBT stress test).

4. The property prediction system for a semiconductor element, according to claim 1,
wherein the properties of the semiconductor element are Id-Vg characteristics or Id-Vd characteristics.

5. The property prediction system for a semiconductor element, according to claim 1,
wherein the processing unit is configured to quantify the qualitative data using Label Encoding.
